(19) United States
(12) Patent Application Publication
(10) Pub. No.: US 2004/0166446 A1
(43) Pub. Date: Aug. 26, 2004

(54) Method for manufacturing metal master of information recording disc and metal master

(75) Inventor: Yuuichi Kawaguchi, Tokyo (JP)

Correspondence Address: OLIFF & BERRIDGE, PLC, P.O. BOX 19928, ALEXANDRIA, VA, 22320, US

(73) Assignee: TDK CORPORATION, Tokyo (JP)

(21) Appl. No.: 10/785,072

(22) Filed: Feb. 25, 2004

(30) Foreign Application Priority Data
Feb. 26, 2003 (JP) 2003-049348

(51) Int. Cl. G03F 7/00

(52) U.S. Cl. 430/320

(57) ABSTRACT

A metal master having higher shape precision than conventional ones and a method for manufacturing such metal master are provided. The metal master has a conductive film having a thickness of about 50 nm (that is within a range of 35 to 200 nm).

### BACKGROUND OF THE INVENTION

1. Field of the Invention

The present invention relates to a method for manufacturing a metal master for fabrication of information recording disc substrates and to a metal master.

2. Description of the Related Art

It is crucial in fabrication of an information recording substrate such as an optical disc that the disc substrate has high shape precision because if a shape error in such disc substrate is large, it will lead to large variation in reflectance, which will decrease the accuracy of recording/reproducing information.

A typically known method for manufacturing an information recording disc substrate involves the steps of applying a positive type photoresist for example on a glass substrate, irradiating the photoresist with a laser beam, developing and removing the exposed photoresist to produce a glass master with fine depressions and protrusions, copying the fine depressions and protrusions of the glass master to a metal master and then to a stamper, and arranging the stamper in a mold for molding resin to fabricate an information recording disc substrate. The information recording disc substrate manufactured according to this method has an information recording region in which pits and/or grooves are formed by depressions and protrusions copied from the glass master in a reversed fashion, namely the depressions are copied as protrusions and the protrusions are copied as depressions. However, it is possible to provide an information recording disc substrate having pits and/or grooves identical to depressions and protrusions of the glass master (equally copied) if a mother is produced by copying the depressions and protrusions of the metal master thereto and then a stamper is produced by copying the protrusions and depressions of the mother thereto. It is also possible to provide an information recording disc substrate having pits and/or grooves identical to depressions and protrusions of the glass master (equally copied) if the metal master is used as a stamper.

The term “metal master” used herein shall be defined as a matrix obtained by removing a conductive film and an electrolytic plating layer formed on a glass master. In other words, herein, any matrix obtained by removing a conductive film and an electrolytic plating layer formed on a glass master shall be called a metal master whether it is used as a stamper or as a matrix for fabricating a stamper or mother.

The terms “pits” and “grooves” are generally used in relation to CD media (Compact Discs) or DVD media (Digital Versatile Discs) to mean fine depressions formed on an information recording disc substrate for recording information therein. In the present specification, however, the terms “pits” and “grooves” shall be used, for the sake of convenience, to mean fine projections as well as fine depressions formed on such an information recording disc substrate that has a light-transmitting layer formed thereon and receives laser beams from the side of this light-transmitting layer.

In the prior art, an information recording disc substrate having high shape precision has been produced by fabricating a high-precision glass master by smoothly polishing a glass substrate and copying the high-precision glass master to a metal master or the like.

It should be noted, however, that even a glass master with high shape precision produced in this manner may generate a slight shape error when the shape of a glass master is copied to a metal master. For example, if the formation of a conductive film or an electrolytic plating layer is defective, or if the conductive film and the electrolytic plating layer are peeled off from each other, the shape error will be increased to an extent such that a metal master thus produced is not usable. For coping with this problem, various technologies have been developed to form a conductive film and an electrolytic plating layer such that the shape error of a metal master can be minimized (see, for example, Japanese Patent Publication No. 2663912). As a result, the shape error in a metal master now rarely poses a problem in practical use.

Nevertheless, comparing information recording discs with equivalent shape errors, those with shallower pits and/or grooves tend to exhibit larger variation in reflectance.

In recent years, there has been a tendency that information recording discs with shallower pits and/or grooves than conventional ones are increased to cope with the situation such as the increase of capacity of information recording discs or the diversification of recording methods. For example, as for DVD-R media (Digital Versatile Discs-Recordable), the depth of grooves is approximately 150 nm, and as for MD media (Mini Discs), the depth of grooves is approximately 100 nm, whereas as for DVD-RW media (Digital Versatile Discs-Rewritable), the depth of grooves is typically approximately 30 nm.

Also, there has been proposed an information recording disc with large capacity in which an information recording disc substrate is provided with a light-transmitting layer with a thickness as small as about 0.1 mm. It is believed that, even in such a large-capacity information recording disc, the depth of grooves is desirably about 30 nm.

As the depth of pits and/or grooves of information recording discs becomes smaller, there has arisen a new problem that a small shape error in metal masters, that is not problematic in conventional technologies, becomes to exert harmful effects to variation in reflectance of information recording discs and hence to decrease the information recording/reproducing accuracy.

### SUMMARY OF THE INVENTION

The present invention has been made in view of the foregoing problems and has an object to provide a metal master with higher shape precision than conventional ones and a method for manufacturing such a metal master.

The present invention has achieved the foregoing object by forming a conductive film of a metal master to have a thickness greater than conventional ones.

Although it is not clearly known why the shape precision of a metal master can be improved by forming a conductive film of the metal master to have a thickness greater than conventional ones, the reason can be largely assumed as follows.

For the formation of a conductive film, a catalyst is applied in the first step, but it is difficult to make the thickness of the catalyst layer uniform. If a conductive film thus is thin, it is believed that nonuniformity in thickness of the catalyst layer will cause nonuniformity in thickness of the conductive film, which affects the electrolytic plating layer, thereby contributing to a small shape error of a metal master. To cope with this problem, a conductive film can be formed thick enough to absorb the nonuniformity in thickness of the catalyst layer, and hence the nonuniformity in thickness of the conductive layer can be minimized. It is believed that a metal master with high shape precision can be formed by forming an electrolytic plating layer on the conductive film with minimal nonuniformity in thickness.

Further, when a conductive film is thin enough for the depth of pits and/or grooves, it is believed that the effect exerted by such thin conductive film to the shape precision of the pits and grooves is small because fine projections of a metal master corresponding to the pits and/or grooves are mainly constituted by an electrolytic plating layer. However, as the depth of pits and/or grooves becomes smaller, the percentage occupied by the conductive film in the constitution of the fine projections of the metal master is increased so that the fine projections are constituted by the conductive film and electrolytic plating layer serving like a composite material, which contributes to a shape error in the fine projections of the metal master. To cope with this, it is believed that the shape error in the fine projections can be decreased by forming the conductive film thick enough such that the projections of the metal master are mainly constituted by the conductive film.

In other words, while it has been believed conventionally that an electrolytic plating layer mainly constitutes a metal master and a conductive film is only an electrode for forming the electrolytic plating layer, the present invention improves the shape precision of a metal master by using a conductive film more positively as a constituent of the metal master. Thus, the present invention has been made based on the view point and conception completely different from the conventional ones.

The forgoing object can be achieved by the invention as described below.

(1) A method for manufacturing a metal master comprising the steps of:

forming a conductive film by an electroless plating method on a glass master having fine depressions and protrusions for forming an information recording region of an information recording disc;

forming an electrolytic plating layer by an electrolytic plating method on the conductive film; and

removing the conductive film and the electrolytic plating layer from the glass master to provide a metal master, wherein

the conductive film is formed to have a thickness of 35 to 200 nm.

(2) The method for manufacturing a metal master according to said (1), wherein

the conductive film is formed to have a thickness of 40 nm or more.

(3) The method for manufacturing a metal master according to said (1), wherein

the conductive film is formed to have a thickness of 45 nm or more.

(4) The method for manufacturing a metal master according to said (1), wherein

the conductive film is formed to have a thickness of 50 nm or more.

(5) The method for manufacturing a metal master according to any one of said (1), (2), (3) or (4), wherein

the conductive film is formed to have a thickness of 150 nm or less.

(6) The method for manufacturing a metal master according to any one of said (1), (2), (3) or (4), wherein

the conductive film is formed to have a thickness of 120 nm or less.

(7) The method for manufacturing a metal master according to any one of said (1), (2), (3) or (4), wherein

the conductive film is formed to have a thickness of 90 nm or less.

(8) The method for manufacturing a metal master according to any one of said (1), (2), (3) or (4), wherein

the conductive film is formed to have a thickness of 60 nm or less.

(9) The method for manufacturing a metal master according to any one of said (1), (2), (3) or (4), wherein

the conductive film is formed to have a thickness of 55 nm or less.

(10) A method for manufacturing a metal master comprising the steps of:

forming a conductive film by an electroless plating method on a glass master having fine depressions and protrusions for forming an information recording region of an information recording disc;

forming an electrolytic plating layer by an electrolytic plating method on the conductive film; and

removing the conductive film and the electrolytic plating layer from the glass master to provide a metal master, wherein

the conductive film is formed to have a thickness greater than a step height of the fine depressions and protrusions of the glass master.

(11) A metal master manufactured with the method for manufacturing a metal master according to any one of said (1), (2), (3), (4), (5), (6), (7), (8), (9) or (10).

(12) A metal master comprising a conductive film having copied fine depressions and protrusions for forming an information recording region of an information recording disc, and an electrolytic plating layer formed on the conductive film, wherein

the conductive film is greater than a step height of the fine depressions and protrusions.

### BRIEF DESCRIPTION OF THE DRAWINGS

FIG. 1 is a cross-sectional view schematically showing the configuration of a metal master according an embodiment of the present invention;

FIG. 2 is a flow chart showing the outline of a method for manufacturing the metal master;

FIG. 3 is a flow chart showing the details of the steps for forming a conductive film of the metal master;

FIG. 4 is a cross-sectional view schematically showing the steps of forming a glass master used for the manufacture of the metal master;

FIG. 5 is a cross-sectional view schematically showing the steps of forming a conductive film of the metal master;

FIG. 6 is a cross-sectional view schematically showing the steps of forming an electrolytic plating layer of the metal master; and

FIG. 7 is a graph showing the relationship between electroless plating time and thickness of a conductive film.

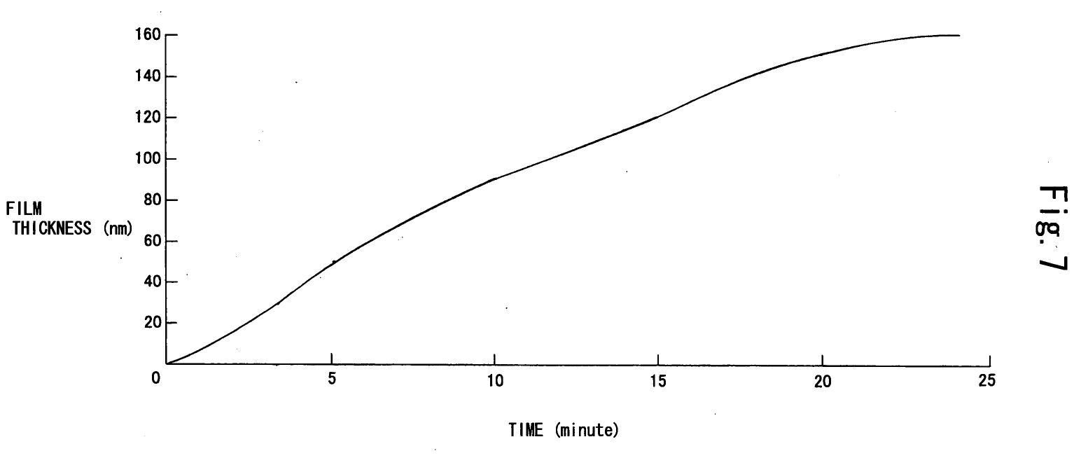

### DETAILED DESCRIPTION OF THE PREFERRED EMBODIMENTS

An embodiment of the present invention will be described in a detailed manner with reference to the drawings. It should be noted that, here, the description will be made taking an example of producing a glass master by using a positive-type photoresist and manufacturing a metal master used for manufacture of a DVD-type information recording disc.

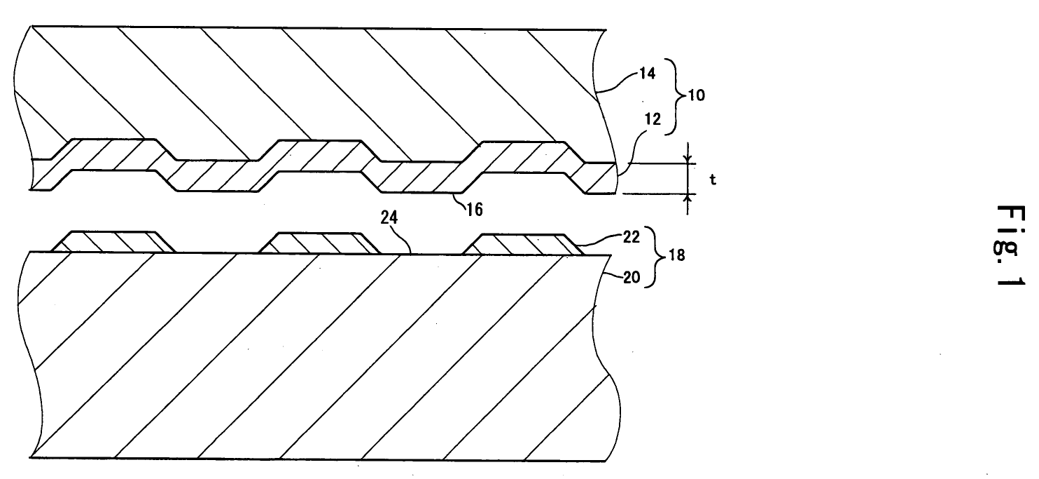

FIG. 1 is a cross-sectional view schematically showing the configuration of a metal master according to the present embodiment.

A metal master 10 is constituted by a laminate of a conductive film 12 and an electrolytic plating layer 14, and is characterized in that the conductive film 12 has a thickness t of about 50 nm (that is within the range of 35 to 200 nm). Since the other structural features of this metal master are similar to those of the conventional ones, the description will be omitted where appropriate.

The conductive film 12 is made of a thin circular disc plate of nickel having a thickness of about 50 nm as described above. The conductive film 12 is provided with fine protrusions 16, which correspond to grooves of an information recording disc, formed in a helical manner. The fine protrusion 16 has a height (step height) of about 30 nm. This means that the thickness of the conductive film 12 is greater than the height of the fine protrusion 16.

The electrolytic plating layer 14 is also made of a thin circular disc plate of nickel and is formed on the opposite surface of the conductive film 12 from the fine protrusion 16. The electrolytic plating layer 14 has a thickness of about 300 μm.

The reference numeral 18 in FIG. 1 indicates a glass master used for producing the metal master 10. The glass master 18 is provided with fine depressions 24 on a glass substrate 20, which correspond to grooves of an information recording disc, by using a positive type photoresist 22. The fine depressions 24 are formed for copying the fine protrusions 16 to the conductive film 12 of the metal master 10 and have a depth of about 30 nm.

Next, a method for manufacturing the metal master 10 will be described.

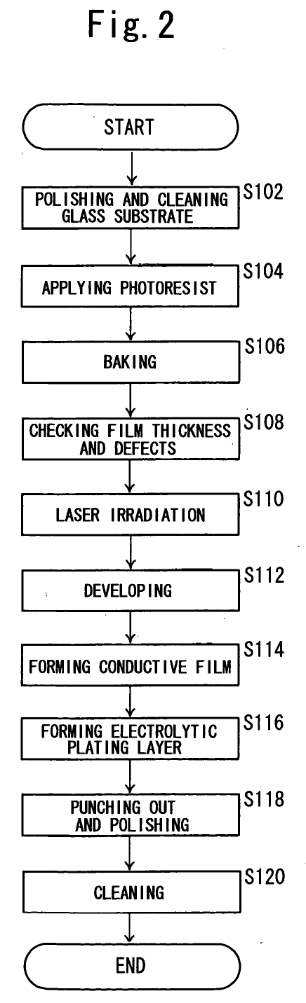

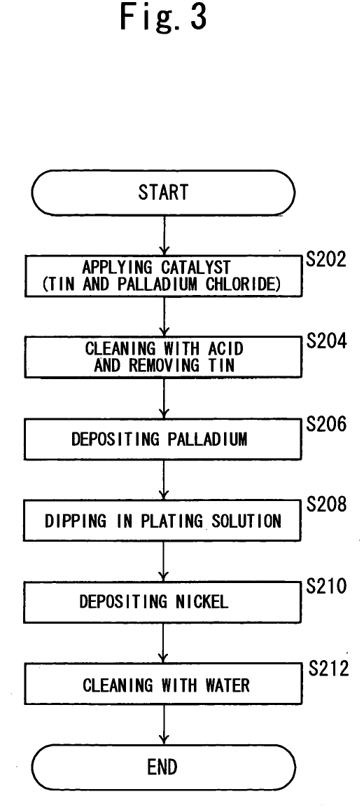

FIG. 2 is a flow chart showing the outline of manufacturing steps of the metal master 10 and FIG. 3 is a flow chart showing the details of steps for forming the conductive film 12.

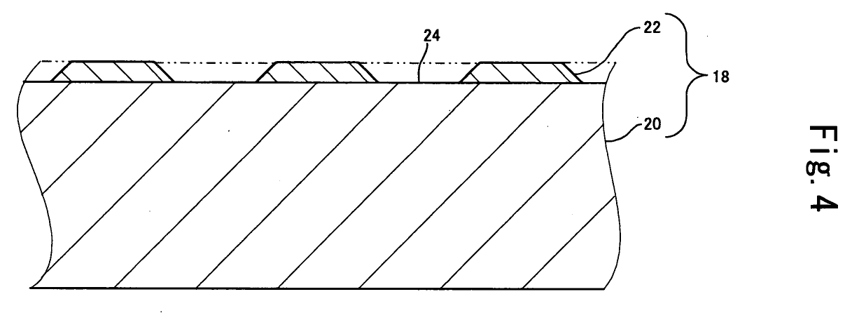

In the first step, the glass substrate 20 is smoothly polished and cleaned (S102). After forming a thin film of an adhesive material on the polished surface, the photoresist 22 is applied by the spin coating method to a thickness of about 30 nm (S104). The photoresist 22 is then baked to evaporate a solvent therein and dried (S106). Thereafter, the photoresist 22 is checked for the thickness and defects (S108). Further, the photoresist 22 is developed (S112) after being irradiated with a laser beam in a pattern corresponding to the helical pattern of the grooves, whereby, as shown in FIG. 4 (S110), an exposed region (region indicated by the two-dot chain line in FIG. 4) is removed to form the fine depressions 24.

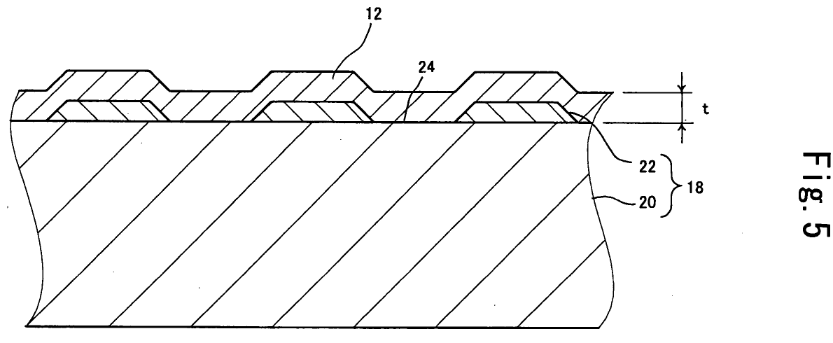

The glass master 18 thus obtained is then provided with the conductive film 12 formed according to the steps as shown in FIG. 3 (S114). Describing more particularly, a colloidal catalyst containing tin and palladium chloride is applied on the glass master 18 by the spin coating method in the first step (S202), and then cleaned with acid to remove tin (S204). As a result, palladium is deposited on the surface of the glass master 18 (S206). When the glass master having palladium deposited on the surface is dipped in (electroless) nickel plating solution (S208), nickel is deposited with the palladium serving as a catalyst (S210). The nickel thus deposited then serves as a catalyst so that further nickel is deposited continuously. By dipping the glass master 18 in the nickel plating solution for about five minutes, the glass master 18 is provided with the conductive film 12 with a thickness of about 50 nm as shown in FIG. 5. The glass master 18 having the conductive film 12 formed thereon is cleaned (S212) before being checked for appearance and the like.

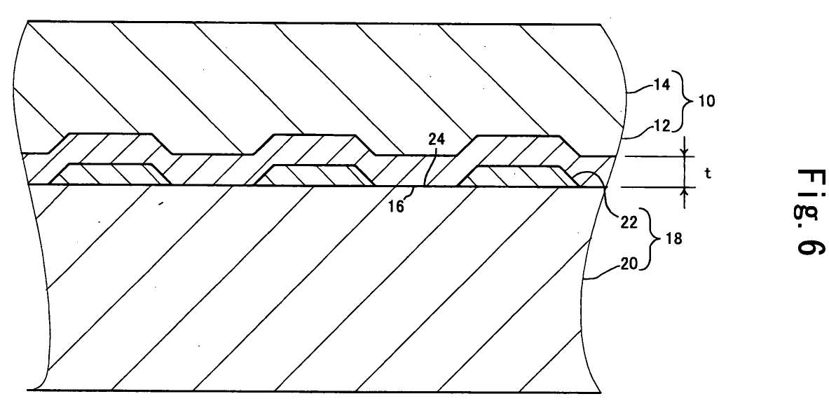

The glass master 18 is then dipped in nickel sulfamate solution and supplied with electricity by using the conductive film 12 as an electrode, so that the nickel film is grown to a thickness of about 300 μm to form an electrolytic plating layer 14 as shown in FIG. 6 (S116). Further, after polishing the opposite surface of the electrolytic plating layer 14 from the conductive film 12 (S118), the conductive film 12 and the electrolytic plating layer 14 are integrally removed from the glass master 18. If necessary, the shape of the conductive film 12 and the electrolytic plating layer 14 may be adjusted by punching out the inner or outer periphery thereof. The photoresist is removed with caustic soda, and the conductive film 12 and the electrolytic plating layer 14 are further subjected to ultrasonic cleaning using ultra pure water (S120). The metal master 10 is completed in this manner.

By using the metal master 10 thus obtained as a stamper, it is possible to form in an information recording disc substrate (not shown in the drawings) grooves with a concave shape corresponding to the fine depressions 24 of the glass master 18.

Further, if a stamper (not shown in the drawings) is fabricated using the metal master 10 by the same electrolytic plating method as described above, it is possible to form in an information recording disc (not shown in the drawings) grooves with a convex shape corresponding to the fine depressions 24 of the glass master 18.

Furthermore, if a mother (not shown in the drawings) is fabricated using the metal master 10 by the same electrolytic plating method as described above and a stamper (not shown in the drawings) is fabricated using the mother by the same electrolytic plating method as described above, it is possible to form in an information recording disc substrate (not shown in the drawings) grooves with a concave shape corresponding to the fine depressions 24 of the glass master 18.

### EXAMPLE

The height of the fine protrusion of the metal master according to the embodiment as described above was set to about 30 nm, and metal masters were fabricated having a conductive film with a thickness of 40, 50, 60, 90, 120, 150, and 200 nm, respectively. Using these metal masters, 100 information recording discs having grooves with a depth of about 30 nm were manufactured for each of the metal masters. These information recording discs were checked for variation in reflectance along the groove thereof. All the results were favorable.

It should be noted that the variation in reflectance as mentioned herein was determined by using a Pulstec DDU1000 tester. The information recording disc was irradiated with a laser beam in the state where tracking was off while focusing on, and reflectance along the groove thereof was measured by measuring an amount of feedback light for the irradiated laser beam so that variation in reflectance was determined. In addition, variation in reflectance in the surface was also determined in a similar manner.

### COMPARATIVE EXAMPLE

For comparing with the above example, metal masters were fabricated having a conductive film with a thickness of 20 and 30 nm, respectively. Using these metal masters, 100 information recording discs having grooves with a depth of about 30 nm were manufactured for each of the metal masters. These information recording discs were checked for variation in reflectance along the groove thereof. In the information recording disc fabricated with the metal master having a conductive film with a thickness of 20 nm, the variation in reflectance was completely over an allowable range. In the information recording disc fabricated with the metal master having a conductive film with a thickness of 30 nm, the variation in reflectance was slightly over the allowable range.

Although the thickness of the conductive film 12 is set to about 50 nm in the foregoing embodiment, the present invention is not limited to this, and the thickness of the conductive film 12 may be selected from a range of 35 to 200 nm according to a depth of a pit, a groove, or the like. Specifically, in the case of forming shallow grooves with a depth of about 30 nm, the conductive film may be formed to have a thickness of 35 nm or more, that is larger than the depth of the groove, so that the shapes of the fine protrusions of the metal master corresponding to the grooves can be stabilized. On the other hand, considering productivity, durability and so on, it is preferable to set the upper limit of the thickness of the conductive film to about 200 nm.

In order to stabilize the shapes of the fine protrusions of the metal master more reliably, it is preferable to form the conductive film to have a thickness of 40 nm or more. Further, in order to stabilize the shapes of the fine protrusions of the metal master still more reliably, it is more preferable to form the conductive film to have a thickness of 45 nm or more. In order to form the fine protrusions of the metal master further more accurately, it is still more preferable to form the conductive film to have a thickness of 50 nm or more.

On the other hand, using a typical electroless plating method, the growth of a conductive film tends to rapidly slow down when the thickness of the conductive film exceeds about 150 nm. Therefore, the conductive film is preferably formed to have a thickness of 150 nm or less. In order to improve the productivity more, it is more preferable to form the conductive film to have a thickness of 120 nm or less. If the thickness of the conductive film is 90 nm or less, the productivity can be improved still more. Further, if the thickness of the conductive film is 60 nm or less, the productivity can be improved further more, and the productivity can be improved still further more by forming the conductive film to have a thickness of 55 nm or less.

Thus, the thickness of the conductive film may be selected appropriately from the above-mentioned range according to a depth (or height) of a pit or a groove of an information recording disc to be formed and according to a type of a functional layer, such that variation in reflectance can be limited reliably to such a range as will not pose any problem in practical use and a desirable productivity can be achieved.

Although the metal master is provided with fine protrusions corresponding to grooves of an information recording disc according to the foregoing embodiment, the present invention is not limited to this and is applicable also to a metal master that is provided with fine protrusions corresponding to pits of an information recording disc. Further, the present invention is also applicable to a metal master that is provided with fine depressions corresponding to grooves and/or pits of an information recording disc.

Further, although the foregoing embodiment is described taking an example of producing a metal master used for the manufacture of a DVD-type optical disc, the present invention is not limited to this and is also applicable to a metal master that is used for the manufacture of other types of information recording discs, such as an information recording disc utilizing optical near-field.

As described above, according to the present invention, desirable effects can be obtained such as that a metal master can be produced with higher shape precision than conventional ones and variation in reflectance of an information recording disc with shallow pits and/or grooves can be restricted to an allowable range.

What is claimed is:

1. A method for manufacturing a metal master comprising the steps of:
forming a conductive film by an electroless plating method on a glass master having fine depressions and protrusions for forming an information recording region of an information recording disc;
forming an electrolytic plating layer by an electrolytic plating method on the conductive film; and
removing the conductive film and the electrolytic plating layer from the glass master to provide a metal master, wherein
the conductive film is formed to have a thickness of 35 to 200 nm.

2. The method for manufacturing a metal master according to claim 1, wherein
the conductive film is formed to have a thickness of 40 nm or more.

3. The method for manufacturing a metal master according to claim 1, wherein
the conductive film is formed to have a thickness of 45 nm or more.

4. The method for manufacturing a metal master according to claim 1, wherein
the conductive film is formed to have a thickness of 50 nm or more.

5. The method for manufacturing a metal master according to claim 1, wherein
the conductive film is formed to have a thickness of 150 nm or less.

6. The method for manufacturing a metal master according to claim 1, wherein
the conductive film is formed to have a thickness of 120 nm or less.

7. The method for manufacturing a metal master according to claim 1, wherein
the conductive film is formed to have a thickness of 90 nm or less.

8. The method for manufacturing a metal master according to claim 1, wherein
the conductive film is formed to have a thickness of 60 nm or less.

9. The method for manufacturing a metal master according to claim 1, wherein
the conductive film is formed to have a thickness of 55 nm or less.

10. A method for manufacturing a metal master comprising the steps of:
forming a conductive film by an electroless plating method on a glass master having fine depressions and protrusions for forming an information recording region of an information recording disc;
forming an electrolytic plating layer by an electrolytic plating method on the conductive film; and
removing the conductive film and the electrolytic plating layer from the glass master to provide a metal master, wherein
the conductive film is formed to have a thickness greater than a step height of the fine depressions and protrusions of the glass master.

11. A metal master comprising a conductive film having copied fine depressions and protrusions for forming an information recording region of an information recording disc, and an electrolytic plating layer formed on the conductive film, wherein
the conductive film has a thickness in the range of 35 to 200 nm and is greater than a step height of the fine depressions and protrusions.

12. The metal master according to claim 11, wherein
the thickness of the conductive film is 40 nm or more.

13. The metal master according to claim 11, wherein
the thickness of the conductive film is 45 nm or more.

14. The metal master according to claim 11, wherein
the thickness of the conductive film is 50 nm or more.

15. The metal master according to claim 11, wherein
the thickness of the conductive film is 150 nm or less.

16. The metal master according to claim 11, wherein
the thickness of the conductive film is 120 nm or less.

17. The metal master according to claim 11, wherein
the thickness of the conductive film is 90 nm or less.

18. The metal master according to claim 11, wherein
the thickness of the conductive film is 60 nm or less.

19. The metal master according to claim 11, wherein
the thickness of the conductive film is 55 nm or less.
